(19) United States
(12) Patent Application Publication
(10) Pub. No.: US 2009/0184341 A1
(43) Pub. Date: Jul. 23, 2009

(54) Elimination of STI recess and facet growth in embedded silicon-germanium (eSiGe) module

(75) Inventors: Yung Fu Chong, Singapore (SG); Lee Wee Teo, Singapore (SG); Shyue Seng Tan, Singapore (SG); Chung Foong Tan, Singapore (SG)

Correspondence Address: DOCKET CLERK, P.O. DRAWER 800889, DALLAS, TX, 75380, US

(73) Assignee: Chartered Semiconductor Manufacturing, Ltd., Singapore (SG)

(21) Appl. No.: 12/009,204

(22) Filed: Jan. 17, 2008

(51) Int. Cl. H01L 27/092; H01L 21/8238

(52) U.S. Cl. 257/190; 438/221; 257/E27.062; 257/E21.632

(57) ABSTRACT

A method (and semiconductor device) of fabricating a semiconductor device eliminates shallow trench isolation (STI) recess in embedded SiGe p-type field effect transistor (pFET) structures. This increases device performance by improving isolation and decreasing leakage current caused by SiGe facet growth and silicide encroachment at the STI. A mask is selectively formed over the STI and adjacent nFET regions to protect them during formation (e.g., reactive ion etching (RIE)) of the embedded source/drain (S/D) regions of the pFET. The mask also extends over the STI edge by a predetermined distance to cover a portion of the embedded S/D region disposed between the STI and gate structure. This helps protect or isolate the STI region during SiGe layer formation in the defined embedded S/D regions.

### TECHNICAL FIELD

The present disclosure relates generally to devices and methods of fabrication of semiconductor devices, and more particularly to the fabrication of field-effect transistors (FETs) having embedded source/drain (S/D) regions.

### BACKGROUND

Embedded Silicon-Germanium (eSiGe) structures provide enhanced transistor device performance. In complementary metal-oxide semiconductor (CMOS) processing involving eSiGe, shallow trench isolation (STI) is utilized to separate adjacent n-type and p-type transistors. Prior art processing of conventional eSiGe transistors includes the formation of a gate stack followed by Reactive Ion Etching (RIE) and preclean steps in preparation for the epitaxial growth of SiGe to form the S/D regions of p-types transistors.

In conventional processing, a hard mask is selectively formed to isolate the n-type structure region from the adjacent p-type structure region. This mask typically covers (or extends over) and protects about one-half of the STI region during the RIE and preclean steps. During these steps, a substantial portion of the STI is removed thereby forming a substantial STI recess.

It has been determined the recessed STI (or STI recess) may cause facet SiGe growth adjacent the STI allowing silicide formation at the STI edge (and sidewall) (during a silicidation process step). These unwanted characteristics arise due to the recessing and edge exposure of the STI. During the silicidation process occurring after formation of the embedded S/D SiGe regions, silicide is found to have formed at the edge of the recessed STI region (and formed on a portion of the STI sidewall). Such silicide formation has been determined to significantly increase leakage current and degrade isolation.

Accordingly, there is a need to have an improved fabrication process (and resulting devices) that substantially eliminates STI recessing—with its potential for accompanying SiGe facet growth and silicide shorting—and improves isolation without the need for additional processing steps. This further reduces or eliminates leakage current caused by silicide encroachment (silicide shorting).

### SUMMARY

In accordance with one embodiment, there is provided a method of forming a semiconductor device. The method includes providing a substrate having a pFET region, an nFET region and a shallow trench isolation (STI) region positioned between the pFET region and the nFET region. First and second gate structures are formed over the pFET region and nFET region. A hard mask is formed over the nFET region, the STI region and the first gate structure, wherein the hard mask defines S/D regions in the pFET region, extends over an edge of the STI and extends over a portion of the pFET region between the STI region and the first gate structure. Recessed S/D regions in the pFET region of the substrate are formed and a stressor layer is formed within the recessed S/D regions.

In accordance with another embodiment, there is provided a method for forming embedded silicon germanium (SiGe) S/D regions within a p-type field effect transistor (pFET) structure. The method includes providing a substrate having a pFET region with a gate structure and a shallow trench isolation (STI) positioned between the pFET region and an nFET region. A mask is formed over the STI, the gate structure and a portion of the substrate extending between the STI and the gate structure, such that the mask defines source/drain (S/D) regions in the pFET region. Recessed S/D regions are formed in the pFET region of the substrate corresponding to the mask and an SiGe layer is formed within the recessed S/D regions to form embedded S/D regions, wherein the SiGe layer has a top surface positioned substantially at or above a top surface of the STI.

In yet another embodiment, there is provided a semiconductor device including a substrate having a pFET region, an nFET region and a shallow trench isolation (STI) region positioned between the pFET region and the nFET region, the STI region having a top surface. The device further includes a first gate structure over the pFET region and a second gate structure over the nFET region. Source/drain (S/D) regions are embedded in the pFET region of the substrate, with the embedded S/D regions including silicon germanium (SiGe) having p-type dopant material and the SiGe has a top surface positioned substantially at or above a top surface of the STI region.

Other technical features may be readily apparent to one skilled in the art from the following figures, descriptions, and claims.

### BRIEF DESCRIPTION OF THE DRAWINGS

For a more complete understanding of the present disclosure, and the advantages thereof, reference is now made to the following descriptions taken in conjunction with the accompanying drawings, wherein like numbers designate like objects, and in which:

FIG. 1 is a cross-sectional view illustrating a typical configuration of an SiGe pFET;

FIG. 2 is a cross-sectional view illustrating a SiGe pFET in accordance with the present disclosure; and

FIGS. 3-9 are cross-sectional views illustrating various steps of a method or process in accordance with the present disclosure.

### DETAILED DESCRIPTION

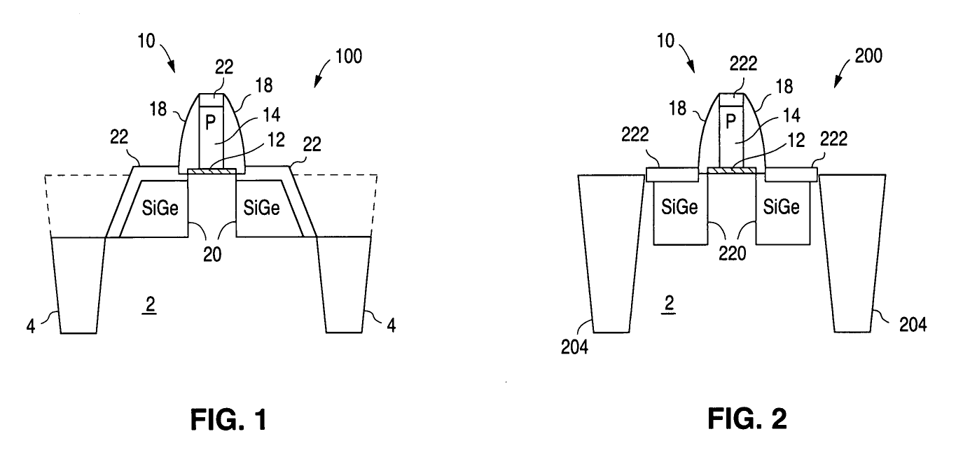

Referring to FIG. 1, there is depicted a cross-sectional view of a typical configuration of an SiGe p-type field-effect transistor (pFET) structure 100. Though the single SiGe pFET structure 100 is shown formed on a silicon substrate 2 between two shallow trench isolation (STI) regions 4, additional p-type transistors or structures may be included therein. The pFET structure 100 includes a gate stack 10 having a gate dielectric 12, a polysilicon gate 14 and sidewall spacers 18. Two p-type SiGe regions 20 form the source/drain (S/D) regions. A silicide layer 22 is formed on the gate 14 and the S/D regions 20, as shown.

The pFET structure 100 was formed in accordance with prior art processing techniques in which reactive ion etching (RIE) or other etching technique removes a portion of the silicon substrate 2 as well as a portion of the STI regions 4. As described above, formation of the SiGe p-type S/D regions 20 involves selectively forming a mask to isolate the p-type structure 100 from one or more adjacent n-type structures (adjacent to the STI regions 4, not shown in FIG. 1). This mask covers and protects the adjacent n-type structure and typically about one-half of the STI 4 during RIE and preclean steps. However, this leaves a substantial portion of the STI 4 unprotected. Further processing of the semiconductor device removes a substantial portion of the STI 4. FIG. 1 includes two dotted lines illustrating the approximate upper locations of the original STI regions 4 prior to STI recess. As shown, all or substantially all of the SiGe S/D regions 20 in the prior art structure 100 are positioned significantly above the resulting STI region 4. As described above, this substantial STI recess causes two problems: (1) poor isolation properties and highly leaky junctions when the subsequent silicide encroaches into the edge of the recessed STI region, and (2) formation of SiGe facet adjacent to the STI region, thus degrading the pFET performance.

Now turning to FIG. 2, there is shown a cross-sectional view of one embodiment of a p-type field-effect transistor (pFET) structure 200 (p-channel MOSFET) in accordance with this present disclosure. This single SiGe pFET structure 200 is shown formed on the silicon substrate 2 between two shallow trench isolation (STI) regions 204, additional p-type transistors or structures may be included therein. Substrate 2 may include, for example, silicon, silicon-on-insulator (SOI), or other suitable semiconductor substrate materials, now known or later developed. The substrate 2 may include silicon (e.g., n-type, p-type, or no type) provided in a single well or twin-well process. The pFET structure 200 includes a similar gate stack 10 having gate dielectric 12, polysilicon gate 14 and sidewall spacers 18. Two p-type SiGe regions 220 form the source/drain (S/D) regions. A silicide layer 222 is formed on the gate 14 and the S/D regions 220, as shown. The pFET structure 200 was formed in accordance with the method or process more fully described below. It may be possible that methods or process other than as described below may be utilized to form the pFET structure 200.

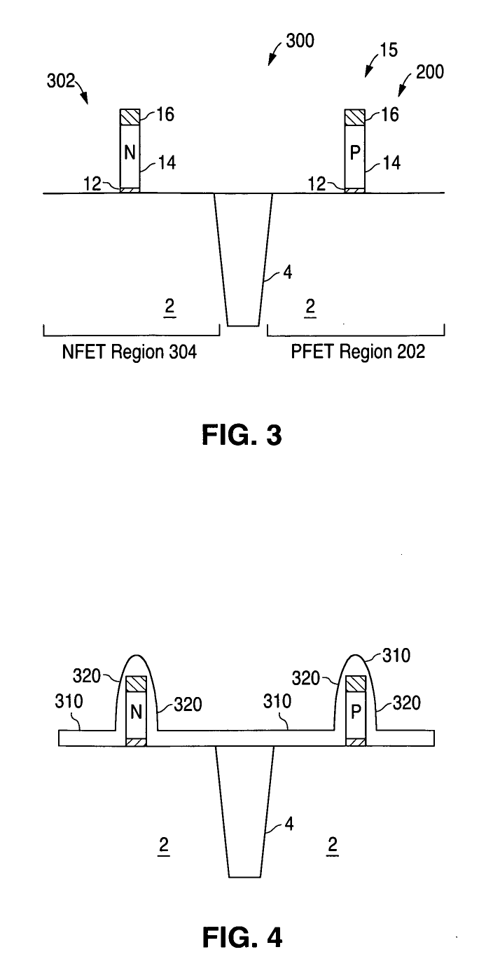

Now referring to FIGS. 3-9, there are shown cross-sectional views of a process in accordance with this disclosure. With specific reference to FIG. 3, there is shown the initial structure 300 including the initial pFET structure 200 having pFET region 202 and an initial nFET structure 302 having an NFET region 304 with an STI region 4 positioned in between pFET region 202 and nFET region 304, all on the substrate 2. It will be understood that the substrate 2 may include additional nFET, pFET and STI structures, though not shown in FIGS. 3-9. Formed on each side of the STI region 4 are gate stacks or structures 15 with gate dielectric 12, polysilicon gate 14 and gate nitride cap 16 which are shown in FIG. 3 without the spacers 18. These structures may be formed in accordance with known techniques.

Now referring to FIG. 4, a next step in the process includes forming a hard mask layer (or a dummy spacer layer) 310 over the initial structure 300. Hard mask layer 310 may be formed using silicon oxide or silicon nitride or combinations thereof. The hard mask layer 310 is deposited using low pressure chemical vapor deposition (LPCVD), plasma enhanced chemical vapor deposition (PECVD) or rapid thermal chemical vapor deposition (RTCVD).

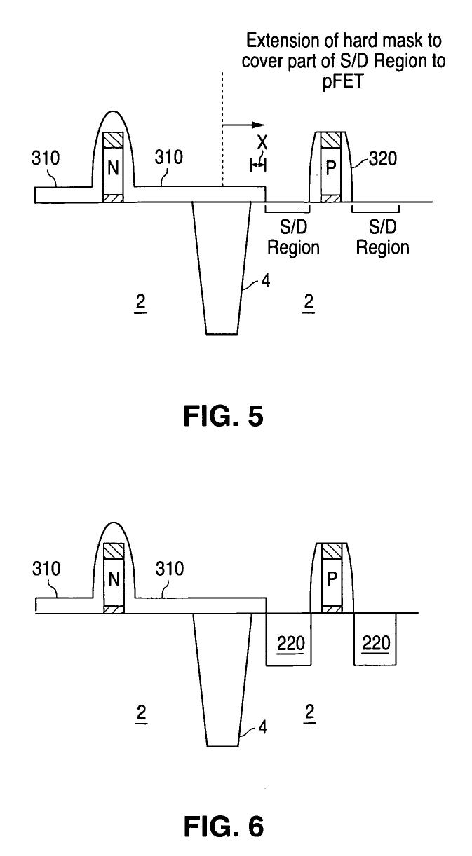

Referring to FIG. 5, a next step in the process includes selectively removing portions of the hard mask layer via lithography to define the S/D regions 220 and form dummy sidewall spacers 320. After a lithography/patterning step, we perform an etch to remove the exposed hard mask layer 310. This results in selective formation of the mask layer 310 over the nFET region 304 (structure 302), the pFET gate stack 15, and the entire portion of the STI regions 4 isolating/separating the S/D regions of the nFET 302 from the S/D regions of the pFET 200. The resulting hard mask layer 310 functions not only to define the S/D regions 220 within the pFET region 202 of the pFET 200 but also as a dummy spacer for the gate stack 15 of the pFET 200 and a protective layer for the STI 4. The hard mask layer 310 also extends over the STI region 4 to cover a portion of the S/D region 220 (nearest the STI 4). As described above, conventional techniques extend the hard mask layer over only about one-half of the STI region 4. The hard mask layer 310 described herein extends over the entire relevant STI region 4 and extends further beyond the edge of the STI region 4 to cover a portion of the S/D region 220. The dimension of this extension is between 5 to 3000 nm.

The extension of the mask boundary 310 (as compared to the prior art) may be done by Boolean (a set of logical operations) sizing during mask generation. The Boolean may also be customized, such that a specific distance may be specified (distance to extend from the original boundary or from the edge of STI) based on current inline overlay and other processing control. Further, the Boolean may be selectively applied for specific devices/structures. In addition, the hard mask extension may be in the horizontal or vertical direction. This allows for no changes in design rules and no change to a device/IC design.

Though not shown, extension and halo implants may be formed for the pFET structure 200 after forming the dummy spacers 320. In one embodiment, these may be formed as described below.

Now referring to FIG. 6, a next step may include removing or recessing a portion of substrate 2 to define or form the recessed S/D regions 220 of the pFET structure 200. It will be understood that the extended mask 310 prevents the exposure of any vertical (and horizontal) surfaces of the STI region 4 during the removal process. Thus, no portion (or no substantial portion) of the STI 4 is removed or becomes recessed. In one embodiment, the material is removed by applying a RIE process, though other material removal processes may be used. Depth of removal will depend on the desired characteristics.

Optionally, an insulating layer may be formed over substrate 2, more particularly, over the bottom surface of the recessed or embedded S/D regions 220, as described in United States Patent Application Publication No. 2007/0278591.

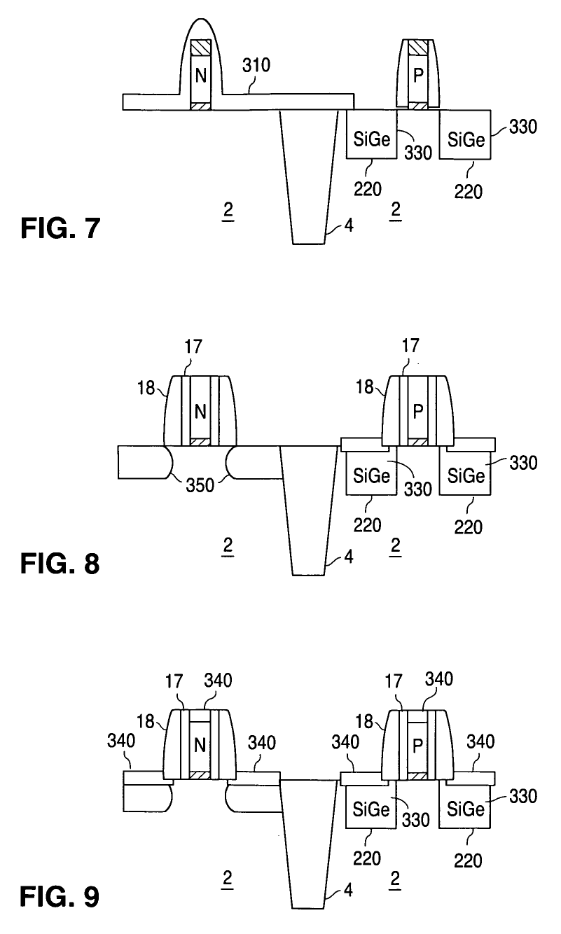

Next, as shown in FIG. 7, a stressor material 330 is formed in the recessed S/D regions 220. Formation of the stressor material 330 may include employing an epitaxy (both lateral and vertical) process, such as epitaxially growing silicon germanium (SiGe) which is suitable for p-type MOSFETs. The SiGe layer 330 substantially fills the recessed S/D regions to a level approximately at or slightly above a top surface of the STI region 4. The layer 330 has a top surface positioned at or slightly above a top surface of the STI 4. By inclusion of substrate 2 covering the sidewalls of the STI 4 (i.e., leaving substrate 2 protecting the STI sidewall surfaces), any facet growth SiGe on the STI 4 is eliminated or substantially reduced. Silicon carbon (SiC) is suitable for n-type MOSFETs.

It will be understood that the processes and methods described herein for fabrication of P-type devices are similarly applicable to N-type devices, such as utilizing SiC as a stressor material. For P-type devices, SiGe is one known material that may be used as the stressor, but others may be used and the stressor material is not limited to SiGe.

Now referring to FIG. 8, the remaining nitride cap 16 and mask layer 310 are removed along with all or a portion of the dummy spacers 320, and the sidewall offset spacers 17 are subsequently formed. Conventional techniques are then performed to complete the fabrication of the pFET structure 200 and nFET structure 302. For example, it will be appreciated that the offset spacers 17 may or may not include a residual portion of the dummy spacers 320. Though not illustrated in the FIGURES, the offset spacers 17 may extend over a portion of the SiGe S/D regions 220. Extension or halo implants are formed by implanting p-type impurities within the substrate underneath at least a portion of the offset spacers 17. Similarly, extension or halo implants are formed by implanting n-type impurities into nFET structure 302. Following these, sidewall spacers 18 are formed on pFET 200 and nFET 302. P-type impurities or dopant are implanted into the S/D regions 220 to form source/drain junctions. Optionally, the stressor material 330 (the S/D regions 220) may be doped in situ (during stressor layer formation), if desired. N-type impurities or dopant are implanted into nFET 302 to form source/drain junctions 350. Additional high temperature annealing (e.g., >800 degrees C.) typically follows (not shown).

Now referring to FIG. 9, a silicide layer 340 is selectively formed on the structure 300 on top of the gate stacks 15, on nFET S/D regions 350 and on the S/D regions 220 of the pFET 200. As shown, the silicide layer 340 extends from the STI 4 to the sidewall spacers of the FET structures 200, 302 and is formed over the stressor layer 330 in the S/D regions. Now known or later developed processes are employed in forming silicide 340, which may include nickel silicide (NiSi), cobalt silicide (CoSi₂), tungsten silicide (WSi), titanium silicide (TiSi), and the like.

The processing steps or methods described above, in conjunction with other known steps, form a pFET MOSFET 200 as described and illustrated in FIG. 2. By forming a mask layer to protect the STI region (disposed between a p-type structure and an n-type structure) and define the S/D regions of the p-type structure, STI recess is eliminated or substantially reduces and isolation is improved. The mask layer extends over an edge of the STI to cover a portion of the substrate lying between the STI and gate structure. This helps eliminate facet growth of SiGE adjacent the STI in the embedded S/D regions and prevents silicide formation at the STI edge, thereby reducing leakage current originating from silicide encroachment. The resultant structure improves pFET device performance, especially in narrow width devices where a large fraction of SiGe device volume is lost due to facet growth.

The present disclosure further improves process stability of SiGe epitaxy since growth of SiGe on silicon is more stable as compared to growth of SiGe on portions of the STI regions. The methods described herein may be implemented with no changes to design rules or IC designs.

The order of steps or processing can be changed or varied form that described above. It will be understood well known process have not been described in detail and have been omitted for brevity. Although specific steps, insulating materials, conductive materials and apparatuses for depositing and etching these materials may have been described, the present disclosure may not limited to these specifics, and others may substituted as is well understood by those skilled in the art.

It may be advantageous to set forth definitions of certain words and phrases used throughout this patent document. The terms “include” and “comprise,” as well as derivatives thereof, mean inclusion without limitation. The term “or” is inclusive, meaning and/or. The phrases “associated with” and “associated therewith,” as well as derivatives thereof, mean to include, be included within, interconnect with, contain, be contained within, connect to or with, couple to or with, be communicable with, cooperate with, interleave, juxtapose, be proximate to, be bound to or with, have, have a property of, or the like.

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A method for forming a semiconductor device, the method comprising:
providing a substrate having a pFET region, an nFET region and a shallow trench isolation (STI) region positioned between the pFET region and the nFET region;
forming a first gate structure over the pFET region and a second gate structure over the nFET region;
forming a mask over the nFET region, the STI region and the first gate structure, the mask defining S/D regions in the pFET region, the mask extending over an edge of the STI and extending over a portion of the pFET region between the STI region and the first gate structure;
forming recessed S/D regions in the pFET region of the substrate; and
forming a stressor layer within the recessed S/D regions.

2. The method in accordance with claim 1 wherein forming the recessed S/D regions in the pFET region further comprises:
removing portions of the substrate using reactive ion etching (RIE).

3. The method in accordance with claim 1 wherein forming the silicon layer comprises:
epitaxially growing silicon germanium (SiGe).

4. The method in accordance with claim 3 further comprising:
removing the mask;
forming offset spacers on the first gate structure;
implanting p-type impurities within the substrate underneath at least a portion of the sidewall spacers;
forming sidewall spacers on the first gate structure; and implanting p-type impurities within the epitaxially grown SiGe within the S/D regions.

5. The method in accordance with claim 4 further comprising;
forming silicide regions over the SiGe within the recessed S/D regions.

6. The method in accordance with claim 3 wherein the epitaxial SiGe layer substantially fills the recessed S/D regions to a level approximately at or slightly above a top surface of the STI region.

7. The method of in accordance with claim 1 wherein the mask extends over the edge of the STI by approximately 5 to 3000 nm.

8. A method for forming embedded silicon germanium (SiGe) S/D regions within a p-type field effect transistor (pFET) structure, the method comprises:
providing a substrate having a pFET region with a gate structure and a shallow trench isolation (STI) positioned between the pFET region and an nFET region;
forming a mask over the STI, the gate structure and a portion of the substrate extending between the STI and the gate structure, the mask defining source/drain (S/D) regions in the pFET region;
forming recessed S/D regions in the pFET region of the substrate corresponding to the mask; and
forming an SiGe layer within the recessed S/D regions to form embedded S/D regions, the SiGe layer having a top surface positioned substantially at or slightly above a top surface of the STI.

9. The method in accordance with claim 8 wherein forming the SiGe layer comprises:
epitaxially growing the SiGe layer.

10. The method in accordance with claim 9 wherein forming the recessed S/D regions in the pFET region further comprises:
removing portions of the substrate using reactive ion etching (RIE).

11. The method in accordance with claim 10 further comprising:
removing the mask;
forming offset and sidewall spacers on the first gate structure; and
implanting p-type impurities into the epitaxially grown SiGe within the S/D regions.

12. The method in accordance with claim 11 further comprising:
forming silicide regions over the SiGe within the recessed S/D regions.

13. The method of in accordance with claim 8 wherein the forming the mask further comprises:
forming the mask to extend over the edge of the STI such that the portion of the substrate extending between the STI and the gate structure and covered laterally by the mask is approximately 5 to 3000 nm.

14. A semiconductor device comprising:
a substrate having a pFET region, an nFET region and a shallow trench isolation (STI) region positioned between the pFET region and the nFET region, the STI region having a top surface;
a first gate structure over the pFET region;
a second gate structure over the nFET region; and
embedded source/drain (S/D) regions in the pFET region of the substrate, the embedded S/D regions comprising silicon germanium (SiGe) having p-type dopant material, the SiGe having a top surface positioned substantially at or slightly above a top surface of the STI region.

15. The device in accordance with claim 14 wherein the SiGe is epitaxial SiGe.

16. The device in accordance with claim 14 wherein one of the S/D regions is separated from the STI region by the substrate in the pFET region.

17. The device in accordance with claim 14 further comprising;
silicide regions over the embedded S/D regions.
